(19) United States
(12) Patent Application Publication
(10) Pub. No.: US 2014/0174918 A1
(43) Pub. Date: Jun. 26, 2014

(54) Sputter Gun

(71) Applicant: INTERMOLECULAR, INC., San Jose, CA (US)

(72) Inventors: Hong Sheng Yang, Pleasanton, CA (US); Kent Riley Child, Dublin, CA (US); Chi-I Lang, Cupertino, CA (US); Jingang Su, Cupertino, CA (US); Danny Wang, Saratoga, CA (US)

(73) Assignee: Intermolecular, Inc., San Jose, CA (US)

(21) Appl. No.: 13/721,419

(22) Filed: Dec. 20, 2012

(51) Int. Cl. C23C 14/35

(52) U.S. Cl. CPC C23C 14/35
USPC 204/298.09; 204/298.16

(57) ABSTRACT

A sputter gun is provided. The sputter gun includes a target and a first plate coupled to a surface of the target. A first magnet is disposed over a second magnet. A second plate coupled to a surface of the first magnet and a gap is defined between a surface of the second magnet and a surface of the first plate. A fluid inlet and a fluid outlet are disposed above a surface of the first magnet. A restriction bar is coupled to the second plate, wherein the restriction bar is configured to prevent a flow path of fluid through the first inlet to the second inlet unless the fluid traverses the gap defined between a surface of the second magnet and a surface of the first plate. Alternative configurations of the sputter gun are included.

### BACKGROUND

Physical vapor deposition (PVD) is commonly used within the semiconductor industry as well as solar, glass coating, and other industries, in order to deposit a layer over a substrate. Sputtering is a common physical vapor deposition method where atoms or molecules are ejected from a target material by high-energy particle bombardment and then deposited onto the substrate.

In order to identify different materials, evaluate different unit process conditions or parameters, or evaluate different sequencing and integration of processes, and combinations thereof, it may be desirable to be able to process different regions of the substrate differently. This capability, hereinafter called “combinatorial processing”, is generally not available with tools that are designed specifically for conventional full substrate processing. Furthermore, it may be desirable to subject localized regions of the substrate to different processing conditions (e.g., localized deposition) in one step of a sequence followed by subjecting the full substrate to a similar processing condition (e.g., full substrate deposition) in another step.

Current full-substrate PVD tools used in the semiconductor industry have a large sputtering source including a large sputtering target, i.e., the target is larger than the substrate in order to deposit a uniform layer on the substrate, even for substrates as large as 300 mm wafer. Alternatively, some full substrate PVD tools use a smaller sputtering source, e.g., 3″ or 4″ diameter target, and rotate the wafer in order to deposit a uniform film, where the substrate may be 200 mm diameter or smaller and the sputtering source is pointed to approximately the mid-radius of the substrate. In these methods, the target-to-substrate spacing is relatively large, e.g., 200 mm, requiring significant space between the sputtering source and the substrate in order to deposit a uniform film on the full substrate.

Combinatorial processing chambers typically include smaller sputtering sources. However, deposition rates can suffer. A plurality of small sputtering sources aimed at a common location on a substrate must be positioned at a significant distance from the substrate to ensure good uniformity of the deposited film within an isolated spot. Particularly for thick film applications such as the formation of metal and metal nitride electrodes, process times of several hours are common. Significant contamination and poor film quality are common byproducts of long processing time.

### SUMMARY

In some embodiments, a sputter gun is provided. The sputter gun includes a target and a first plate coupled to a surface of the target. A first magnet is disposed over a second magnet. A second plate coupled to a surface of the first magnet and a gap is defined between a surface of the second magnet and a surface of the first plate wherein the surface of the second magnet opposes the surface of the first plate. A fluid inlet and a fluid outlet are disposed above a surface of the first magnet. A restriction bar is coupled to the second plate, wherein the restriction bar is configured to prevent a flow of fluid through the first inlet to the second inlet unless the fluid traverses the gap defined between a surface of the second magnet and a surface of the first plate.

In some embodiments, a sputter gun is provided. The sputter gun includes a target having a first surface and a side surface extending from the first surface. The target has a recess extending from a second surface of the target towards the first surface. A first magnet is disposed within the recess and a second magnet is disposed adjacent to the side surface.

In some embodiments, a sputter gun is provided. The sputter gun includes a shunt plate having a plurality of holes defined there through. A plurality of magnets is affixed to the shunt plate, each magnet of the plurality of magnets is affixed through a member extending through a hole of the shunt plate into a recess or threaded hole of an end of each magnet of the plurality of magnets, wherein an axis of the recess/threaded hole is offset from an axis of the magnet.

### BRIEF DESCRIPTION OF DRAWINGS

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration.

FIG. 3 is a simplified schematic diagram illustrating an integrated high productivity combinatorial (HPC) system in accordance with some embodiments of the invention

FIG. 4 is a simplified schematic diagram illustrating a sputter chamber configured to perform combinatorial processing and full substrate processing in accordance with some embodiments of the invention.

FIGS. 5A and 5B are simplified schematic diagrams illustrating a stacked magnet configuration for a process gun with a relatively small form factor in accordance with one embodiment.

FIG. 6 is a simplified schematic diagram illustrating a shunt plate enabling a universal magnet assembly in accordance with some embodiments.

FIG. 7 is a simplified schematic diagram for a magnet utilized with the shunt plate of FIG. 6 in accordance with some embodiments.

FIG. 8 is a simplified schematic diagram illustrating a magnetron design providing for an increased target life in accordance with some embodiments.

### DETAILED DESCRIPTION

The embodiments described herein provide a method and apparatus related to sputter deposition processing. It will be obvious, however, to one skilled in the art, that the present invention may be practiced without some or all of these specific details. In other instances, well known process operations have not been described in detail in order not to unnecessarily obscure the present invention.

Semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning HPC processing techniques have also been successfully adapted to deposition processes such as physical vapor deposition (PVD), atomic layer deposition (ALD), and chemical vapor deposition (CVD).

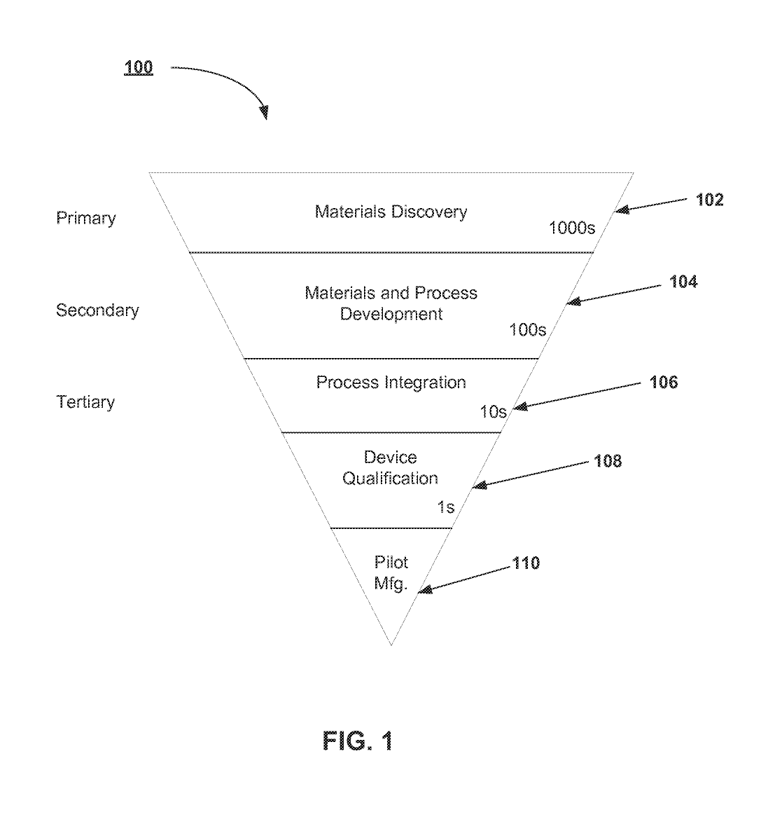

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

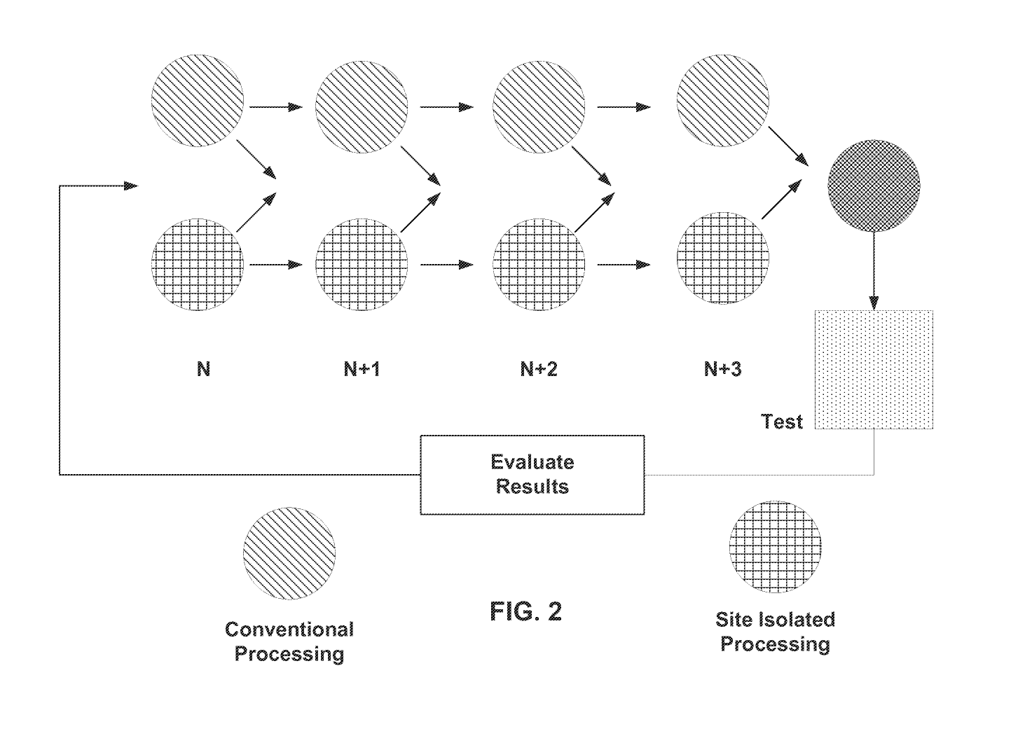

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

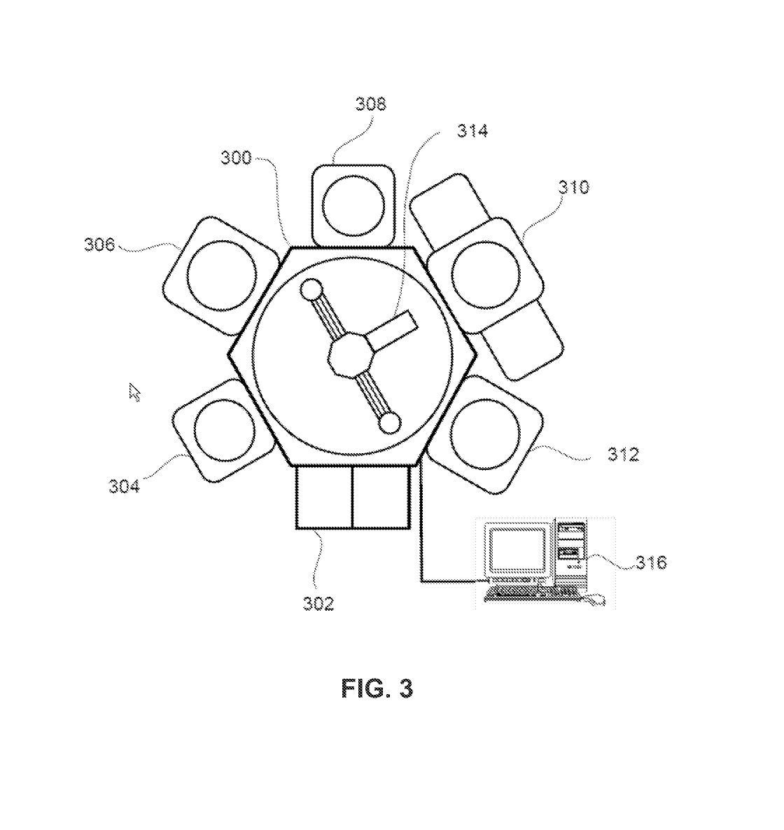

FIG. 3 is a simplified schematic diagram illustrating an integrated high productivity combinatorial (HPC) system in accordance with some embodiments of the invention. HPC system includes a frame 300 supporting a plurality of processing modules. It should be appreciated that frame 300 may be a unitary frame in accordance with some embodiments. In some embodiments, the environment within frame 300 is controlled. Load lock/factory interface 302 provides access into the plurality of modules of the HPC system. Robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system, including the power supplies and synchronization of the duty cycles described in more detail below. Further details of one possible HPC system are described in U.S. application Ser. Nos. 11/672,478 and 11/672,473. With HPC system, a plurality of methods may be employed to deposit material upon a substrate employing combinatorial processes.

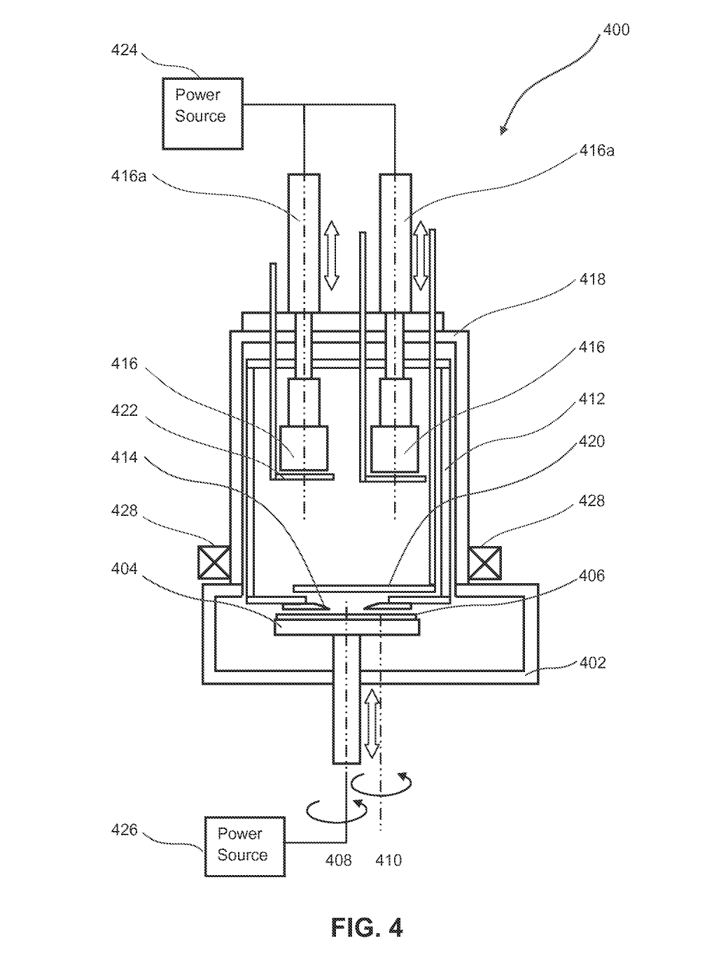

FIG. 4 is a simplified schematic diagram illustrating a sputter chamber configured to perform combinatorial processing and full substrate processing in accordance with some embodiments of the invention. Processing chamber 400 includes a bottom chamber portion 402 disposed under top chamber portion 418. Within bottom portion 402, substrate support 404 is configured to hold a substrate 406 disposed thereon and can be any known substrate support, including but not limited to a vacuum chuck, electrostatic chuck or other known mechanisms. Substrate support 404 is capable of both rotating around its own central axis 408 (referred to as “rotation” axis), and rotating around an exterior axis 410 (referred to as “revolution” axis). Such dual rotary substrate support is central to combinatorial processing using site-isolated mechanisms. Other substrate supports, such as an XY table, can also be used for site-isolated deposition. In addition, substrate support 404 may move in a vertical direction. It should be appreciated that the rotation and movement in the vertical direction may be achieved through known drive mechanisms which include magnetic drives, linear drives, worm screws, lead screws, a differentially pumped rotary feed through drive, etc. Power source 426 provides a bias power to substrate support 404 and substrate 406, and produces a negative bias voltage on substrate 406. In some embodiments power source 426 provides a radio frequency (RF) power sufficient to take advantage of the high metal ionization to improve step coverage of vias and trenches of patterned wafers. In another embodiment, the RF power supplied by power source 426 is pulsed and synchronized with the pulsed power from power source 424. Further details of the power sources and their operation may be found in U.S. patent application Ser. No. 13/281,316 entitled “High Metal Ionization Sputter Gun” filed on Oct. 25, 2011 and is herein incorporated by reference for all purposes.

Substrate 406 may be a conventional round 200 mm, 300 mm, or any other larger or smaller substrate/wafer size. In some embodiments, substrate 406 may be a square, rectangular, or other shaped substrate. One skilled in the art will appreciate that substrate 406 may be a blanket substrate, a coupon (e.g., partial wafer), or even a patterned substrate having predefined regions. In another embodiment, substrate 406 may have regions defined through the processing described herein. The term region is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field a region may be, for example, a test structure, single die, multiple dies, portion of a die, other defined portion of substrate, or an undefined area of a substrate, e.g., blanket substrate which is defined through the processing.

Top chamber portion 418 of chamber 400 in FIG. 4 includes process kit shield 412, which defines a confinement region over a radial portion of substrate 406. Process kit shield 412 is a sleeve having a base (optionally integrated with the shield) and an optional top within chamber 400 that may be used to confine a plasma generated therein. The generated plasma will dislodge atoms from a target and the sputtered atoms will deposit on an exposed surface of substrate 406 to combinatorial process regions of the substrate in some embodiments. In another embodiment, full wafer processing can be achieved by optimizing gun tilt angle and target-to-substrate spacing, and by using multiple process guns 416. Process kit shield 412 is capable of being moved in and out of chamber 400, i.e., the process kit shield is a replaceable insert. In another embodiment, process kit shield 412 remains in the chamber for both the full substrate and combinatorial processing. Process kit shield 412 includes an optional top portion, sidewalls and a base. In some embodiments, process kit shield 412 is configured in a cylindrical shape, however, the process kit shield may be any suitable shape and is not limited to a cylindrical shape.

The base of process kit shield 412 includes an aperture 414 through which a surface of substrate 406 is exposed for deposition or some other suitable semiconductor processing operations. Aperture shutter 420 which is moveably disposed over the base of process kit shield 412. Aperture shutter 420 may slide across a bottom surface of the base of process kit shield 412 in order to cover or expose aperture 414 in some embodiments. In another embodiment, aperture shutter 420 is controlled through an arm extension which moves the aperture shutter to expose or cover aperture 414. It should be noted that although a single aperture is illustrated, multiple apertures may be included. Each aperture may be associated with a dedicated aperture shutter or an aperture shutter can be configured to cover more than one aperture simultaneously or separately. Alternatively, aperture 414 may be a larger opening and plate 420 may extend with that opening to either completely cover the aperture or place one or more fixed apertures within that opening for processing the defined regions. The dual rotary substrate support 404 is central to the site-isolated mechanism, and allows any location of the substrate or wafer to be placed under the aperture 414. Hence, the site-isolated deposition is possible at any location on the wafer/substrate.

A gun shutter, 422 may be included. Gun shutter 422 functions to seal off a deposition gun when the deposition gun may not be used for the processing in some embodiments. For example, two process guns 416 are illustrated in FIG. 4. Process guns 416 are moveable in a vertical direction so that one or both of the guns may be lifted from the slots of the shield. While two process guns are illustrated, any number of process guns may be included, e.g., one, three, four or more process guns may be included. Where more than one process gun is included, the plurality of process guns may be referred to as a cluster of process guns. Gun shutter 422 can be transitioned to isolate the lifted process guns from the processing area defined within process kit shield 412. In this manner, the process guns are isolated from certain processes when desired. It should be appreciated that slide cover plate 422 may be integrated with the top of the process kit shield 412 to cover the opening as the process gun is lifted or individual cover plate 422 can be used for each target. In some embodiments, process guns 416 are oriented or angled so that a normal reference line extending from a planar surface of the target of the process gun is directed toward an outer periphery of the substrate in order to achieve good uniformity for full substrate deposition film. The target/gun tilt angle depends on the target size, target-to-substrate spacing, target material, process power/pressure, etc.

Top chamber portion 418 of chamber 400 of FIG. 4 includes sidewalls and a top plate which house process kit shield 412. Arm extensions 416a, which are fixed to process guns 416 may be attached to a suitable drive, e.g., lead screw, worm gear, etc., configured to vertically move process guns 416 toward or away from a top plate of top chamber portion 418. Arm extensions 416a may be pivotally affixed to process guns 416 to enable the process guns to tilt relative to a vertical axis. In some embodiments, process guns 416 tilt toward aperture 414 when performing combinatorial processing and tilt toward a periphery of the substrate being processed when performing full substrate processing. It should be appreciated that process guns 416 may tilt away from aperture 414 when performing combinatorial processing in another embodiment. In yet another embodiment, arm extensions 416a are attached to a bellows that allows for the vertical movement and tilting of process guns 416. Arm extensions 416a enable movement with four degrees of freedom in some embodiments. Where process kit shield 412 is utilized, the aperture openings are configured to accommodate the tilting of the process guns. The amount of tilting of the process guns may be dependent on the process being performed in some embodiments. Power source 424 provides power for sputter guns 416 whereas power source 426 provides RF bias power to an electrostatic chuck to bias the substrate when necessary. It should be appreciated that power source 424 may output a direct current (DC) power supply or a radio frequency (RF) power supply.

Chamber 400 includes auxiliary magnet 428 disposed around an external periphery of the chamber. The auxiliary magnet 428 is located in a region defined between the bottom surface of sputter guns 416 and a top surface of substrate 406. Magnet 428 may be either a permanent magnet or an electromagnet. It should be appreciated that magnet 428 is utilized to provide more uniform bombardment of argon ions and electrons to the substrate in some embodiments.

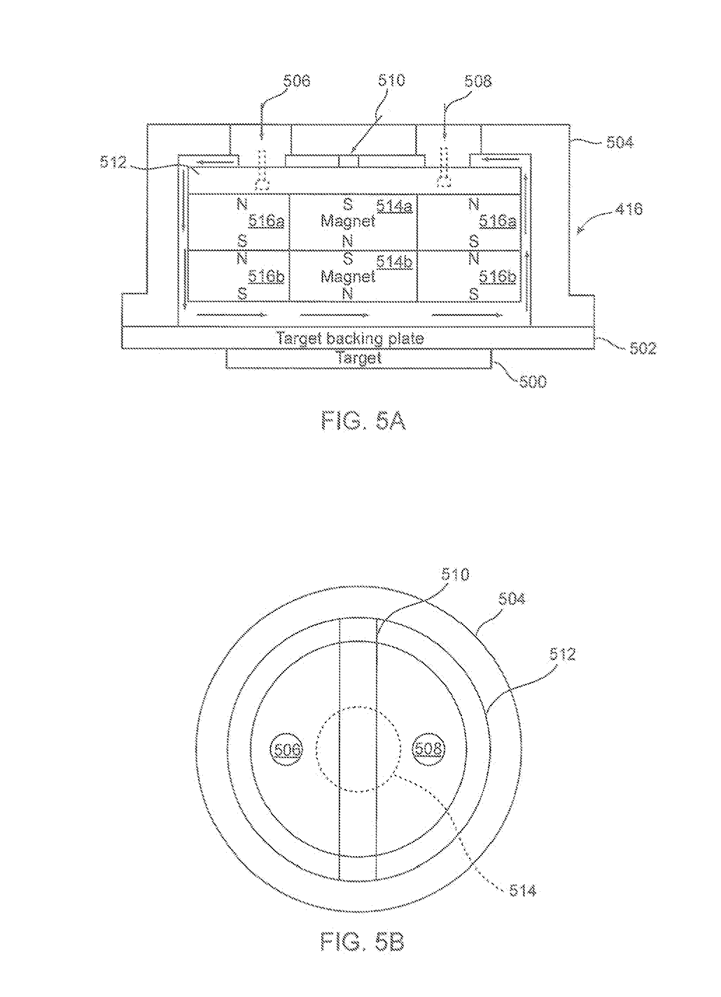

FIGS. 5A and 5B are simplified schematic diagrams illustrating a stacked magnet configuration for a process gun with a relatively small form factor in accordance with some embodiments. FIG. 5A is a cross sectional view of process gun 416 in accordance with some embodiments. Process gun 416 includes target 500 coupled to backing plate 502. Inner magnets 514a and 514b, as well as outer magnets 516a and 516b are assembled in a stacked configuration for achieving higher magnetic field strength where there is no gap between the north and south poles. Alternatively, if a gap is desirable between the north and south poles, it will be filled up with a ring made of non-ferromagnetic and corrosion-resistant materials such as plastics. Plate 512 is disposed over and coupled to a surface of magnets 514a and 516a. Inlet 506 provides access to a cooling fluid that flows along a fluid path defined by a gap between surfaces of housing 504 and magnets 516a, 516b and a gap defined between magnets 516b, 514b and a surface of backing plate 502. Flow restriction bar 510 prevents the flow of fluid from inlet 506 to outlet 508 without the fluid passing through the gap defined between the surfaces of magnets 516b, 514b and a surface of backing plate 502. In other embodiments, target 500 and backing plate 502 are replaced by a monolithic target. As illustrated in the top cross sectional view of FIG. 5B, flow restriction bar 510 extends over a surface of plate 512 along side surfaces of plate 512 between inlet 506 and outlet 508 and along side surfaces of stacked magnets 516a and 516b, which are disposed under plate 512, thereby blocking the flow of fluid along the surfaces of plate 512 and the side surfaces of magnets 516a and 516b. It should be appreciated that restriction bar 510 contacts the inner surface of housing 504. This u-shaped configuration for restriction bar 510 ensures the fluid traverses the gap defined between the surfaces of magnets 516b, 514b and a surface of backing plate 502 to ensure efficient cooling of the target for this compact design of process gun 416.

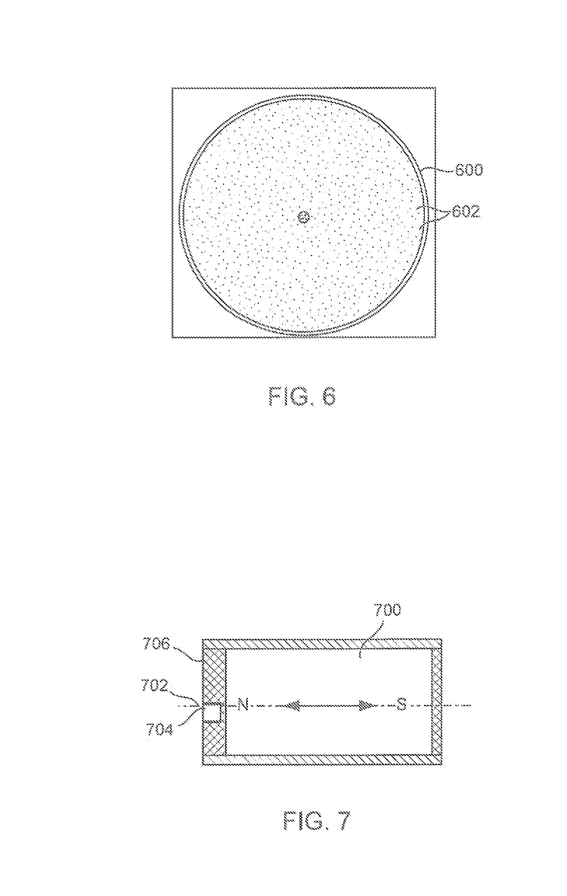

FIG. 6 is a simplified schematic diagram illustrating a shunt plate enabling a universal magnet assembly in accordance with some embodiments. Shunt plate 600 includes a grid of holes 602 disposed throughout the shunt plate. In some embodiments the distance between neighboring rows and columns of holes 602 is about ⅙ of an inch. It should be appreciated that any pattern and distance between holes 602 may be utilized and integrated into the embodiments described herein. For example, in some embodiments the holes may be patterned as concentric rings over plate 600. Shunt plate 600 is composed of any conductive metal in some embodiments.

FIG. 7 is a simplified schematic diagram for a magnet utilized with the shunt plate of FIG. 6 in accordance with some embodiments. Magnet 700 is integrated into a casing having end cap 706. Threaded hole 704 is included within end cap 706. It should be appreciated that threaded hole 704 is off center relative to axis 702 of magnet 700 in some embodiments. The off-centered magnet can be rotated while being screwed into the shunt plate of FIG. 6 so that the center of asymmetry axis can be placed within about 1/18 of an inch of the nearest hole. It should be appreciated that with an overall resolution of about 1/18 of an inch, this embodiment may create any magnet of desirable size and shape for the magnetron. In some embodiments, the assembly of magnets 700 may be accomplished through attaching any suitable magnet to an adapter block with an off centered threaded hole. A bolt can then be used to affix the magnet/adaptor block assembly to the shunt plate of FIG. 6. In alternative embodiments magnet cylinders with a hole in the center can also be used without the end cap affixed thereto. It should be appreciated that the additional freedom offered by the combination of the shunt plate of FIG. 6 and the magnet of FIG. 7 enhances the achievement of uniform films and high ionization. In addition, the embodiments illustrated through FIGS. 6 and 7 enable further combinatorial experiments used to evaluate film deposition. Alternatively, the embodiments of FIGS. 6 and 7 may be integrated into a conventional full processing deposition tool where the deposition gun and the target have a larger diameter than the substrate being processed.

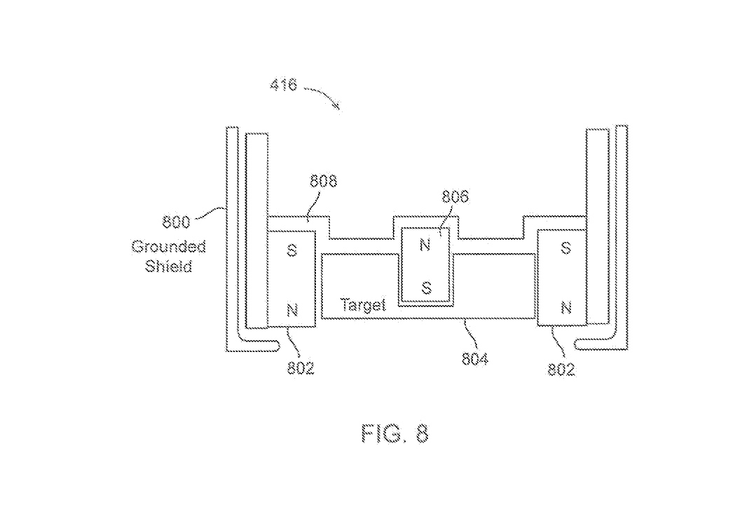

FIG. 8 is a simplified schematic diagram illustrating a magnetron design providing for an increased target life in accordance with some embodiments. Sputter gun 416 is illustrated with grounded shield 800 encompassing magnet 802. Target 804 is disposed within a region defined by the inner surfaces of magnet 802. Magnet 806 is disposed within a recess defined around a center region of target 804. A membrane 808 is provided behind a surface of target 804 and magnets 802 and 806. It should be appreciated that membrane 808 may be utilized to enhance heat transfer in order to cool the target 804 during processing. That is, a flow of cooling fluid may be provided to an outer surface of membrane 808 to cool target 804. In some embodiments, membrane 808 is able to conform to the uneven surfaces of magnets 802 and 806 and target 804. The design illustrated in FIG. 8 allows the use of a relatively thick target where a top-hat shaped target has a recess in a center region. The recess in the center region accommodates an inner magnet 806 partially housed or completely inside the recess. The outer magnet 802 is placed around a sidewall of target 804, rather than behind the target. It should be appreciated that the magnetic field generated between the inner magnet 806 and outer magnet 802 is decoupled and independent from the target thickness. In some embodiments the center region of the target 804 where the recess is defined may be textured to prevent particle issues. In addition, magnets 802 and 806 may have the north and south polarities disposed laterally rather than the vertical orientation illustrated in FIG. 8. It should be appreciated that magnet 802 can move vertically away and towards a substrate surface opposing the target of sputter gun 416. The movement may be correlated to the erosion of the target surface during the processing in some embodiments. The movement of the magnet may or may not be tied to movement of the target/and or the entire sputter gun assembly. In some embodiments the target is composed of a ferromagnetic material. In some embodiments a thickness of the target 804 along the sidewall is about 0.5 inches and a thickness of the center region of the target is about 0.1 inches.

In the drawings, like reference numerals appearing in different drawings represent similar or same components and perform similar or same functions, unless specifically noted otherwise in the description. Furthermore, as would be appreciated by those skilled in the art, according to common practice, the various features of the drawings discussed herein are not necessarily drawn to scale, and that dimensions of various features, structures, or characteristics of the drawings may be expanded or reduced to more clearly illustrate various implementations of the invention described herein.

Implementations of the invention may be described as including a particular feature, structure, or characteristic, but every aspect or implementation may not necessarily include the particular feature, structure, or characteristic. Further, when a particular feature, structure, or characteristic is described in connection with an aspect or implementation, it will be understood that such feature, structure, or characteristic may be included in connection with other implementations, whether or not explicitly described. Thus, various changes and modifications may be made to the provided description without departing from the scope or spirit of the invention. As such, the specification and drawings should be regarded as exemplary only, and the scope of the invention to be determined solely by the appended claims.

What is claimed is:

1. A sputter gun, comprising:
a target;
a first plate coupled to a surface of the target;
a first magnet disposed over a second magnet;
a second plate coupled to a surface of the first magnet;
a gap defined between a surface of the second magnet and a surface of the first plate, wherein the surface of the second magnet opposes the surface of the first plate;
a fluid inlet and a fluid outlet disposed above a surface of the first magnet;
a restriction bar coupled to the second plate, wherein the restriction bar is configured to prevent a flow of fluid from the fluid inlet to the fluid outlet unless the fluid traverses the gap defined between the surface of the second magnet and the surface of the first plate.

2. The sputter gun of claim 1, wherein the restriction bar is coupled to a surface of the first magnet and a surface of the second magnet.

3. The sputter gun of claim 1, wherein the restriction bar is coupled to side surfaces of the second plate.

4. The sputter gun of claim 1, wherein the fluid inlet and the fluid outlet are disposed above the second plate.

5. The sputter gun of claim 1, wherein a diameter of the target is less than a diameter of a substrate processed by the sputter gun.

6. A sputter gun, comprising;
a target having a first surface and a side surface extending from the first surface, the target having a recess extending from a second surface of the target towards the first surface;
a first magnet disposed within the recess; and
a second magnet disposed adjacent to the side surface.

7. The sputter gun of claim 6, wherein the second magnet is operable to move vertically.

8. The sputter gun of claim 6, wherein the side surface of the target is about 0.5 inches thick and wherein a center region of the target is about 0.1 inches thick.

9. The sputter gun of claim 6, wherein the recess is defined within a center region of the second surface.

10. The sputter gun of claim 6, wherein the target is composed of a ferromagnetic material.

11. The sputter gun of claim 6, comprising:
a membrane disposed over a second surface of the target and a top surface of the first magnet and a top surface of the second magnet.

12. The sputter gun of claim 11, comprising;
a fluid pathway defined above the membrane, and wherein the membrane is thermally conductive.

13. The sputter gun of claim 6, wherein the north and south polarities of the second magnet are disposed laterally.

14. The sputter gun of claim 13, wherein the north and south polarities of the first magnet are disposed laterally.

15. A sputter gun, comprising:
a shunt plate having a plurality of holes defined therethrough;
a plurality of magnets affixed to the shunt plate, each magnet of the plurality of magnets affixed through a member extending through a hole of the shunt plate into a recess of an end of each magnet of the plurality of magnets, wherein an axis of the recess is offset from an axis of the magnet.

16. The sputter gun of claim 15, wherein the plurality of holes is arranged in a concentric circle pattern.

17. The sputter gun of claim 15, wherein the member is a bolt.

18. The sputter gun of claim 15 wherein the offset is based on a size of the plurality of holes.

19. The sputter gun of claim 15, wherein the member is threaded and wherein each magnet of the plurality of magnets is encased in an adaptor having the recess.
